(19) United States
(12) Patent Application Publication
(10) Pub. No.: US 2008/0230858 A1
(43) Pub. Date: Sep. 25, 2008

(54) Multi-layer Package Structure for an Acoustic Microsensor

(75) Inventor: Hsin-Tang Chien, Yilan County (TW)

Correspondence Address: WPAT, PC, 7225 BEVERLY ST., ANNANDALE, VA, 22003, US

(73) Assignee: INDUSTRIAL TECHNOLOGY RESEARCH INSTITUTE, Hsin-Chu, TW (TW)

(21) Appl. No.: 12/032,020

(22) Filed: Feb. 15, 2008

(30) Foreign Application Priority Data
Mar. 19, 2007 (TW) 096109300

(51) Int. Cl. H01L 27/00

(52) U.S. Cl. 257/416; 257/E27.001

(57) ABSTRACT

A multi-layer package structure for an acoustic microsensor, the package structure mainly utilizes a stack of multiple substrates for housing and protecting circuit elements such that integrated circuit element and acoustic microsensor arranged in recessions of a substrate can reduce volume of the package structure. By adding various sound hole designs, the problem of larger package volume can be effectively solved and sensing frequency of the acoustic microsensor can be increased simultaneously.

### FIELD OF THE INVENTION

The present invention relates to a multi-layer package structure for an acoustic microsensor, which is utilized for increasing sensing frequency of the acoustic microsensor, more particularly to a multi-layer package structure utilizing a stack of multiple substrates for housing and protecting circuit elements. By adding various sound hole designs in the multi-layer package structure, the package volume of the acoustic microsensor can be effectively reduced and sensing frequency of the acoustic microsensor can be increased simultaneously.

### BACKGROUND OF THE INVENTION

The package for an acoustic microsensor manufactured by Micro ElectroMechanical System (MEMS) technology is a very important issue. In conventional package technology, wire bonding is utilized between an integrated circuit element and an acoustic microsensor. The conventional technology is mature, however, area of the wire and volume of the package must be increased. Therefore, due to larger volume of the conventional package, the acoustic microsensor utilized in the applications such as mini-thin mobile phone, microphone within watch, and audiphone is much limited.

FIG. 1 shows a conventional package structure for an acoustic microsensor, which is disclosed in U.S. Pat. No. 6,781,231 entitled “Microelectromechanical System Package with Environmental and Interference Shield.” In the structure of FIG. 1, surface mount elements 12, 14 and 16, which includes integrated circuit element and acoustic microsensor element, are surface mounted on a substrate 18, respectively, wherein the surface mount elements are connected with each other by wire bonding. Owing to that both of integrated circuit element and acoustic microsensor element need to occupy substrate area and integrated circuit element and acoustic microsensor element are connected with each other by wire bonding, volume of this conventional package structure is large.

FIG. 2 shows another conventional package structure for an acoustic microsensor, which is disclosed in US Patent Application Publication No. 2005/0185812 entitled “Miniature Silicon Condenser Microphone and Method for Producing the Same.” In the structure of FIG. 2, an integrated circuit element 22 and an acoustic microsensor element 24 are still surface mounted on a substrate 26, and a back chamber 28 for the acoustic microsensor is formed below the acoustic microsensor element 24 by drilling the substrate 26 downward to decrease vibration noise generated by a sensing film of the acoustic microsensor. Because both of the integrated circuit element 22 and the acoustic microsensor element 24 still occupy substrate area and the substrate 26 needs to be drilled downward, volume of this conventional package structure is still large and its manufacturing process is more complicated.

Because of larger volume of the above-mentioned conventional package structures, the acoustic microsensor utilized in real applications is easily to generate a resonant frequency in the hearing frequency range 20 Hz-20 KHz of human ears so that the acoustic microsensor generates noises or sounds, which are harmful to the hearing sense of human ears, at the resonant frequency. FIG. 3 shows a resonant frequency measured in the conventional package structure for an acoustic microsensor shown in FIG. 1, the resonant frequency is about 13 KHz and is just located in the hearing frequency range 20 Hz-20 KHz of human ears.

To solve the larger volume problem of conventional package structures, the present invention provides a multi-layer package structure for an acoustic microsensor, the package structure mainly utilizes a stack of multiple substrates for housing and protecting circuit elements such that integrated circuit element and acoustic microsensor arranged in recessions of a substrate can reduce volume of the package structure. By adding various sound hole designs, the problem of larger package volume can be effectively solved and sensing frequency of the acoustic microsensor can be increased simultaneously.

### SUMMARY OF THE INVENTION

The present invention provides a multi-layer package structure for an acoustic microsensor, which utilizes a stack of multiple substrates for housing and protecting circuit elements, to effectively reduce the package volume of the acoustic microsensor and to increase sensing frequency of the acoustic microsensor simultaneously.

The present invention provides a multi-layer package structure for an acoustic microsensor, which adds various sound hole designs around the acoustic microsensor, to reduce the contaminations to the acoustic microsensor due to impurities and water in the air and further to increase sensing frequency of the acoustic microsensor.

To achieve the foregoing objectives, the present invention provides a multi-layer package structure for an acoustic microsensor, the package structure mainly utilizes a stack of multiple substrates for housing and protecting circuit elements such that integrated circuit element and acoustic microsensor arranged in recessions of a substrate can reduce volume of the package structure. By adding various sound hole designs, the problem of larger package volume can be effectively solved and sensing frequency of the acoustic microsensor can be increased simultaneously.

To make the examiner easier to understand the objectives, structure, innovative features, and function of the invention, preferred embodiments together with accompanying drawings are illustrated for the detailed description of the invention.

### BRIEF DESCRIPTION OF THE DRAWINGS

FIG. 1 is a structure diagram of a conventional package structure for an acoustic microsensor.

FIG. 2 is a structure diagram of another conventional package structure for an acoustic microsensor.

FIG. 3 is a diagram of a resonant frequency measured in the conventional package structure for an acoustic microsensor shown in FIG. 1.

FIG. 4 is a three-dimensional diagram of the multi-layer package structure for an acoustic microsensor of the present invention.

FIG. 5 is a structure diagram of the first embodiment of the multi-layer package structure for an acoustic microsensor of the present invention.

FIG. 6 is a structure diagram of the second embodiment of the multi-layer package structure for an acoustic microsensor of the present invention.

FIG. 7 is a structure diagram of the third embodiment of the multi-layer package structure for an acoustic microsensor of the present invention.

FIG. 8 is a structure diagram of the fourth embodiment of the multi-layer package structure for an acoustic microsensor of the present invention.

FIG. 9 is simulation diagram depicting resonant frequency versus package structure volume in the present invention and the prior art shown in FIG. 1.

### DESCRIPTION OF THE PREFERRED EMBODIMENT

FIG. 4 is a three-dimensional diagram of the multi-layer package structure for an acoustic microsensor of the present invention, wherein three substrates 410, 420 and 430 are stacked sequentially from bottom to top. The middle substrate 420 is a substrate with recessions and the two recessions are used to contain an integrated circuit element (or other passive element) and an acoustic microsensor, respectively. Utilizing a stack of multiple substrates for housing and protecting circuit elements can reduce package volume of the acoustic microsensor and increase sensing frequency of the acoustic microsensor simultaneously.

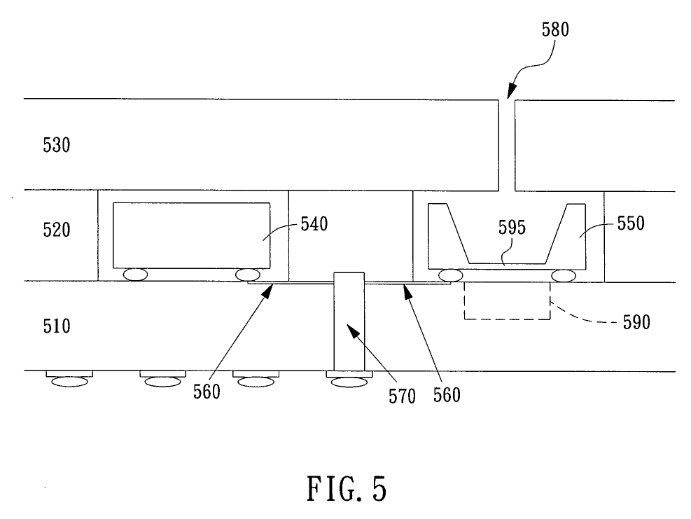

FIG. 5 is a structure diagram of the first embodiment of the multi-layer package structure for an acoustic microsensor of the present invention, wherein a substrate 520 with recessions is stacked on a conducting substrate 510 and a protection substrate 530 is stacked on the substrate 520. Two recessions of the substrate 520 contain an integrated circuit element 540 and an acoustic microsensor 550, respectively, and the integrated circuit element 540 and the acoustic microsensor 550 are surface mounted on the conducting substrate 510 by flip-chip technology. The integrated circuit element 540 and the acoustic microsensor 550 also can be connected by wire bonding, and electrical signals of the integrated circuit element 540 and the acoustic microsensor 550 are sent to the conducting substrate 510 and a system circuit board (not shown) via a conducting wire 560 and a conducting material 570. A sound hole 580 is opened on the protection substrate 530 at a position corresponding to that of the acoustic microsensor 550, and a back chamber 590 of the acoustic microsensor 550 is designed in the conducting substrate 510 at a position corresponding to that of the sound hole 580 to decrease vibration noise generated by a sensing film 595 of the acoustic microsensor 550. The integrated circuit element 540 and the acoustic microsensor 550 also can be surface mounted on the bottom of the protection substrate 530 at a position corresponding to the original one. By utilizing a stack of multiple substrates, the package structure of the first embodiment improves the prior art structure such that the integrated circuit element and the acoustic microsensor contained in recessions of one substrate occupy smaller volume to effectively solve the problem of prior art larger package volume and increase sensing frequency of the acoustic microsensor simultaneously.

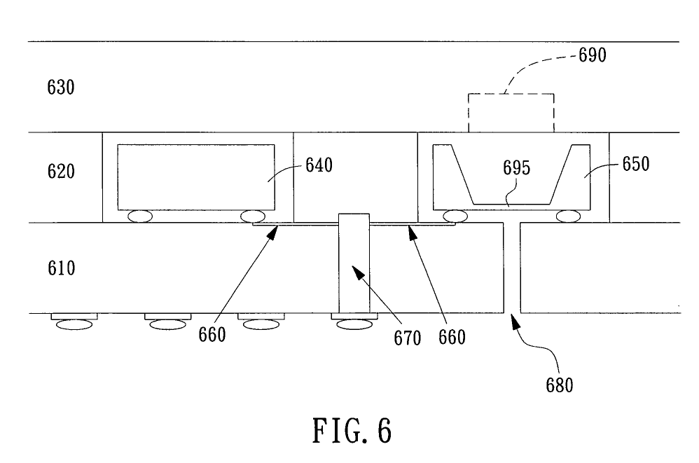

FIG. 6 is a structure diagram of the second embodiment of the multi-layer package structure for an acoustic microsensor of the present invention, wherein the structure and all elements are the same with those in the first embodiment except a different design for the position of the sound hole. In the package structure of the second embodiment, a sound hole 680 is opened on the conducting substrate 610 at a position corresponding to that of the acoustic microsensor 650, and a back chamber 690 of the acoustic microsensor 650 is designed in the protection substrate 630 at a position corresponding to that of the sound hole 680 to decrease vibration noise generated by a sensing film 695 of the acoustic microsensor 650. By utilizing a stack of multiple substrates, the package structure of the second embodiment also improves the prior art structure such that the integrated circuit element and the acoustic microsensor contained in recessions of one substrate occupy smaller volume to effectively solve the problem of prior art larger package volume and increase sensing frequency of the acoustic microsensor simultaneously.

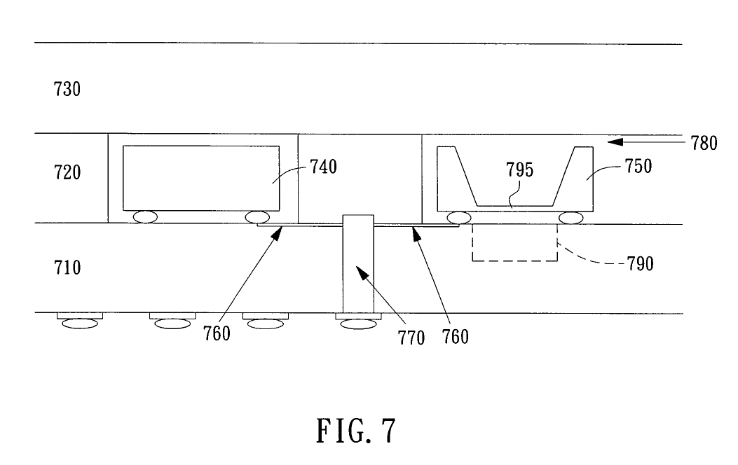

FIG. 7 is a structure diagram of the third embodiment of the multi-layer package structure for an acoustic microsensor of the present invention, wherein the structure and all elements are the same with those in the previous embodiments except a different design for the position of the sound hole. In the package structure of the third embodiment, a side sound hole 780 is opened from outside of the recess containing the acoustic microsensor 750 in the substrate 720, and a back chamber 790 of the acoustic microsensor 750 is designed in the conducting substrate 710 at a position corresponding to that of the side sound hole 780 to decrease vibration noise generated by a sensing film 795 of the acoustic microsensor 750. The back chamber 790 also can be designed at a corresponding position in the protection substrate 730. By utilizing a stack of multiple substrates, the package structure of the third embodiment also improves the prior art structure such that the integrated circuit element and the acoustic microsensor contained in recessions of one substrate occupy smaller volume to effectively solve the problem of prior art larger package volume and increase sensing frequency of the acoustic microsensor simultaneously.

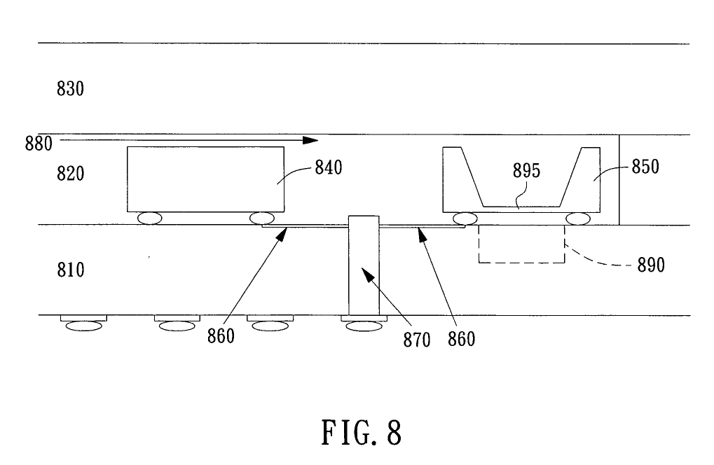

FIG. 8 is a structure diagram of the fourth embodiment of the multi-layer package structure for an acoustic microsensor of the present invention, wherein the structure and all elements are the same with those in the previous embodiments except a different design for the position of the sound hole. In the package structure of the fourth embodiment, a side sound hole 880 is opened from outside of the recess containing the integrated circuit element 840 in the substrate 820 and the part of substrate 820 between the two recesses is removed, so as to greatly keep away impurities and water in the air. Also, a back chamber 890 of the acoustic microsensor 850 is designed in the conducting substrate 810 to decrease vibration noise generated by a sensing film 895 of the acoustic microsensor 850. The back chamber 890 also can be designed at a corresponding position in the protection substrate 830. By utilizing a stack of multiple substrates, the package structure of the fourth embodiment also improves the prior art structure such that the integrated circuit element and the acoustic microsensor contained in recessions of one substrate occupy smaller volume to effectively solve the problem of prior art larger package volume and reduce the contaminations to the acoustic microsensor due to impurities and water in the air, and further to increase sensing frequency of the acoustic microsensor simultaneously.

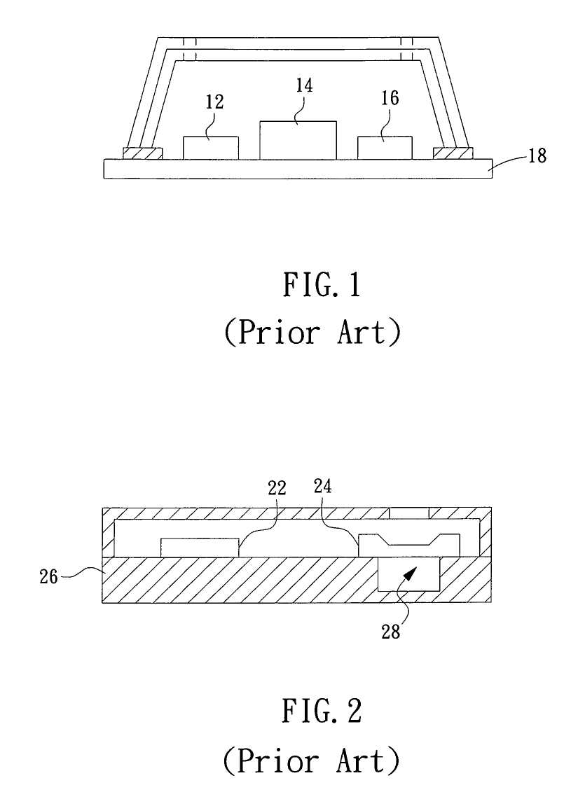

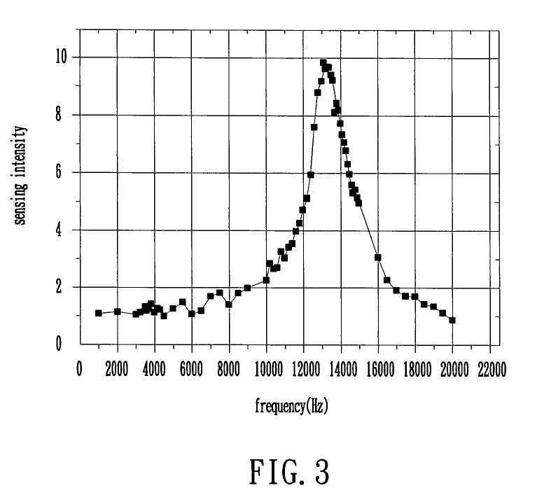

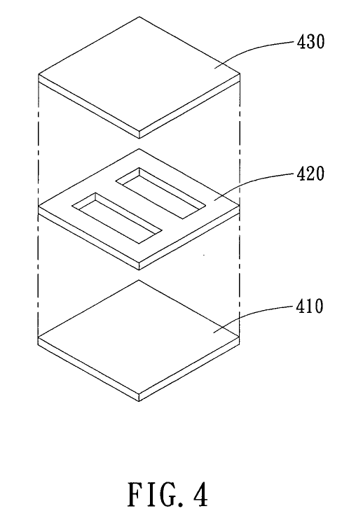

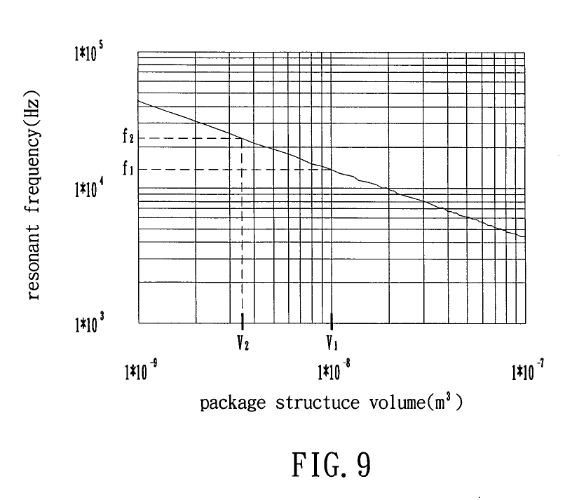

FIG. 9 is a simulation diagram depicting resonant frequency versus package structure volume in the present invention and the prior art shown in FIG. 1. In the prior art shown in FIG. 1, its package structure volume is V1 and its simulated corresponding resonant frequency f1 is about 15 KHz which is approximate to the resonant frequency 13 KHz shown in FIG. 3 which is measured in the conventional package structure for an acoustic microsensor shown in FIG. 1. By the above-mentioned, it is confirmed that due to larger volume of the conventional package structure, the acoustic microsensor is easily to generate a resonant frequency in the hearing frequency range 20 Hz-20 KHz of human ears so that it is harmful to the hearing sense of human ears. However, by utilizing the multi-layer package structure of the present invention, because its package structure volume is reduced to V2 so that its correspondingly generated resonant frequency f2 is about 24 KHz, which is beyond the hearing frequency range 20 Hz-20 KHz of human ears. Therefore, utilizing the multi-layer package structure of the present invention can effectively reduce package structure volume of the acoustic microsensor and increase sensing frequency, and the resonant frequency contained therein, of the acoustic microsensor simultaneously, so as to solve the larger package volume problem of conventional acoustic microsensor package structures and the problem of generating a resonant frequency in the hearing frequency range of human ears.

In addition, the conducting substrate, the substrate with recessions and the protection substrate in the invention are printed circuit boards (PCB). Each surface of the conducting substrate, the substrate with recessions and the protection substrate can be plated with a metal layer to achieve electromagnetic shielding. The conducting substrate, the substrate with recessions and the protection substrate can be made of a metal material, a non-metal material or a composite material, and the conducting substrate, the substrate with recessions and the protection substrate can be made into a whole body. The connections between the integrated circuit element and the conducting substrate, the acoustic microsensor and the conducting substrate, the integrated circuit element and the protection substrate, the acoustic microsensor and the protection substrate, and the integrated circuit element and the acoustic microsensor use an adhesive, a solder ball, a conducting material or a wire. Furthermore, the multi-layer package structure for an acoustic microsensor of the present invention also can be utilized in a pressure sensor, an acceleration sensor or an ultrasound sensor.

In summary, the present invention provides a multi-layer package structure for an acoustic microsensor, the package structure mainly utilizes a stack of multiple substrates for housing and protecting circuit elements such that integrated circuit element and acoustic microsensor arranged in recessions of a substrate can reduce volume of the package structure. By adding various sound hole designs, the problem of larger package volume can be effectively solved and sensing frequency of the acoustic microsensor can be increased simultaneously.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A multi-layer package structure for an acoustic microsensor, comprising:
a conducting substrate;
a substrate with recessions stacked on the conducting substrate, the substrate with recessions has at least two recessions;
at least one integrated circuit element contained in one recession of the recessions of the substrate and mounted on the conducting substrate, the integrated circuit element includes one or more passive elements;
at least one acoustic microsensor contained in another recession of the recessions of the substrate and mounted on the conducting substrate gate;
a protection layer substrate stacked on the substrate with recessions;
wherein electrical connections exist between the integrated circuit element and the conducting substrate, the acoustic microsensor and the conducting substrate, and the integrated circuit element and the acoustic micro sensor.

2. The multi-layer package structure for an acoustic microsensor of claim 1, wherein a sound hole is opened on the protection substrate at a position corresponding to that of the acoustic microsensor, and a back chamber of the acoustic microsensor is designed in the conducting substrate at a position corresponding to that of the sound hole.

3. The multi-layer package structure for an acoustic microsensor of claim 1, wherein a sound hole is opened on the conducting substrate at a position corresponding to that of the acoustic microsensor, and a back chamber of the acoustic microsensor is designed in the protection substrate at a position corresponding to that of the sound hole.

4. The multi-layer package structure for an acoustic microsensor of claim 1, wherein a side sound hole is opened from outside of the recess containing the acoustic microsensor in the substrate, and a back chamber of the acoustic microsensor is designed in the conducting substrate at a position corresponding to that of the side sound hole.

5. The multi-layer package structure for an acoustic microsensor of claim 1, wherein a side sound hole is opened from outside of the recess containing the integrated circuit element 840 in the substrate and the part of substrate between the two recesses is removed, and a back chamber of the acoustic microsensor is designed in the conducting substrate.

6. The multi-layer package structure for an acoustic microsensor of claim 1, wherein the conducting substrate, the substrate with recessions and the protection substrate are printed circuit boards (PCB).

7. The multi-layer package structure for an acoustic microsensor of claim 1, wherein each surface of the conducting substrate, the substrate with recessions and the protection substrate can be plated with a metal layer.

8. The multi-layer package structure for an acoustic microsensor of claim 1, wherein the conducting substrate, the substrate with recessions and the protection substrate can be made of a metal material, a non-metal material or a composite material, and the conducting substrate, the substrate with recessions and the protection substrate can be made into a whole body.

9. The multi-layer package structure for an acoustic microsensor of claim 1, wherein the connections between the integrated circuit element and the conducting substrate, the acoustic microsensor and the conducting substrate, the integrated circuit element and the protection substrate, the acoustic microsensor and the protection substrate, and the integrated circuit element and the acoustic microsensor use an adhesive, a solder ball, a conducting material or a wire.

10. The multi-layer package structure for an acoustic microsensor of claim 1, wherein the multi-layer package structure can be utilized in a pressure sensor, an acceleration sensor or an ultrasound sensor.

11. The multi-layer package structure for an acoustic microsensor of claim 1, wherein the integrated circuit element and the acoustic microsensor are surface mounted on the conducting substrate or the protection substrate by flip-chip technology.
